(19) United States
(12) Patent Application Publication
(10) Pub. No.: US 2026/0171811 A1
(43) Pub. Date: Jun. 18, 2026

(54) PORTABLE DEVICE FOR ENVIRONMENTAL MONITORING AND WEARABLE CHARGING

(71) Applicant: ULTRAHUMAN HEALTHCARE PVT LTD, Bangalore South (IN)

(72) Inventors: Yogansh Namdeo, Bengaluru (IN); Anoop Jayan, Bangalore (IN); Mainak Mitra, West Bengal (IN); Akshay Joshi, Maharashtra (IN); Vishnu Pradeep, Kollam (IN); Gaurav Singh, Gorakhpur (IN); Vinayak MK, Kerala (IN); Mohit Kumar, Bangalore (IN); Bhuvan Srinivasan, Bangalore (IN); Adhit Shet, Bangalore (IN); Vatsal Singhal, Bengaluru (IN)

(73) Assignee: ULTRAHUMAN HEALTHCARE PVT LTD, Bangalore South (IN)

(21) Appl. No.: 19/386,160

(22) Filed: Jan. 31, 2026

Related U.S. Application Data
(63) Continuation-in-part of application No. 19/035,482, filed on Jan. 23, 2025.

(30) Foreign Application Priority Data
Jan. 23, 2024 (IN) 202341079621
Nov. 19, 2025 (IN) 202543114440

(51) Int. Cl. H02J 7/34; G01D 21/02; H02J 7/70; H02J 50/10; H02J 50/90; H04B 5/79; H05K 9/00

(52) U.S. Cl. CPC H02J 7/342; G01D 21/02; H02J 7/731; H02J 50/10; H02J 50/90; H04B 5/79; H05K 9/0022; H02J 2207/30

(57) ABSTRACT

A portable device, comprising: one or more charging docks, wherein the charging dock provides charging to a wearable device connected to the charging dock; a plurality of sensors configured to monitor environment conditions, wherein the environment conditions includes at least one of temperature, humidity, air quality, luminance; a controller connected with the plurality of sensors, wherein the controller is configured to process data received from the plurality of sensors; and a wireless communication module connected with the controller to transmit the processed data; wherein the device transmits the processed data, irrespective of the connection at the charging dock.

The present invention is a continuation-in-part of U.S. application Ser. No. 19/035,482, filed Jan. 23, 2025, which claim priority of Indian Patent Application No. 202341079621, filed Jan. 23, 2024, each of which is hereby incorporated by reference in its entirety. The invention comprises an improvement in/modification of the invention claimed in the specification of the aforementioned application.

### FIELD OF INVENTION

The present invention relates generally to portable electronic devices and, more specifically, to a portable device configured for charging wearable electronics such as smart rings, and for monitoring environmental conditions and user activity in real-time.

### BACKGROUND

An individual/user is exposed to varying levels of environmental conditions in a closed space, such as home or office. The environmental conditions include factors such as varying levels of light, noise, air quality, and radiations. Such environmental conditions highly impact day-to-day life and wellness of the user. However, regular health and fitness monitoring devices, especially smart wearable devices only considers bodily parameters and physiological data of the user.

With advancement in technology, the user is surrounded by smart or electronic devices in his home or office. While on one hand the electronic devices ease life of the user, on another hand the electronic devices may create newer problems and distractions for the user, such as disturbance in sleep, emission of high intensity light, and electromagnetic radiations. Over exposure or ill-timed usage of the electronic devices may contribute to deteriorating wellness of the user.

Current wearable ecosystems often lack a dedicated, portable solution for continuous environmental monitoring. Most health and wellness platforms focus on biometric data from the body but neglect the ambient environmental context—such as temperature, humidity, and air quality—which can significantly influence recovery, sleep, and overall well-being.

The existing technologies suffer from various disadvantages and does not allow for uninterrupted monitoring of external conditions. For example, phone chargers with sensors (e.g., smart clamping chargers) use sensors for proximity or device detection but not for ambient environmental data. Wireless charging ICs (e.g., LTC4126) report power-related metrics but do not report environmental conditions. Charging stations for sensors (e.g., PASCO Wireless Sensor Charging Station) are non-portable and not suited for wearables. Smart rings offer health monitoring but they rely entirely on the ring for sensing and their chargers have no sensing capabilities.

Thus, technologies in the prior art fail to combine wireless charging with real-time environmental sensing in a compact portable form, even when the wearable device is not docked. The present invention overcomes these shortcomings.

### OBJECTS OF THE INVENTION

An objective of the present invention is to provide a portable charging and ambience monitoring device.

Another objective of the invention is to collect environmental data even when the ring is not worn or charging.

Another objective of the invention is to provide a smart ring charger that supports home integration and alerts.

Yet another objective of the invention is to provide more comprehensive and actionable health insights.

### SUMMARY OF THE INVENTION

The present invention relates to a portable device. The portable device may operate as a charging dock for smart wearable devices such as smart rings, and it may function as a standalone environmental monitoring system. The device comprises a charging dock equipped with a wireless charging coil or alternative charging mechanism, a plurality of environmental sensors capable of measuring temperature, humidity, air quality, and luminance, a controller to manage sensor data and device operations, and a wireless communication module to transmit data to other devices.

In one aspect, portable device may comprise wireless charging circuitry for wireless charging of a smart wearable device, such as an electronic ring.

In one aspect, the portable device may be configured to communicate with a server for providing one or more sensor data captured by the plurality of sensors.

In one aspect, the one or more charging docks and the plurality of sensors are positioned as per system-in-package architecture

In an embodiment of the present disclosure, a portable device comprises a plurality of sensors configured to monitor different environmental conditions and user activity. A controller connected with the plurality of sensors. The controller is configured to process data received from the plurality of sensors and a wireless communication module connected with the controller to transmit processed data to a server.

In an aspect of the present disclosure, the environment conditions include at least one of temperature, humidity, air quality, luminance.

In another aspect of the present disclosure, the portable device further comprises an infrared camera connected with the controller to monitor the user activity.

In another aspect of the present disclosure, the wireless communication module operates using Bluetooth, Wi-Fi, or Near Field Communication (NFC).

In another aspect of the present disclosure, the portable device further comprises a wireless charging coil for wireless charging of a smart wearable device.

In another aspect of the present disclosure, the portable device further comprises a speaker for providing notifications and alerts to the user.

In another aspect of the present disclosure, the portable device further communicates with other portable devices present in vicinity, for communicating the data to server.

In another aspect of the present disclosure, the portable device further comprises a power source to power the plurality of sensors, the controller and the wireless module.

In another embodiment of the present disclosure, a server for managing ambient conditions of a user comprises a processor configured to execute instructions for operating one or more IoT devices connected with the portable device. Additionally, the server includes a memory coupled to the processor configured to stores a program readable by the processor for executing a method of operating one or more IoT devices connected with the portable device includes receiving sensor data and user activity data from one of a smart wearable device and the portable device. The server receives user preferences from a user device and sends instructions to the portable device for operating one or more IoT devices connected with the portable device. The instructions are sent based on the sensor data and the user preferences. Furthermore, the server receives information of usage pattern of the IoT devices by the user. The server provides recommendations to the user for storing the information as the user preferences, and sends the instructions, based on a response of the user, to the portable device for operating the one or more IoT devices.

In another aspect of the present disclosure, the recommendations are provided to the user and the user preferences are received from the user through a user device.

In another aspect of the present disclosure, wherein the user device includes a smartphone, tablet, or a laptop.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying drawings constitute a part of the description and are used to provide further understanding of the present invention. Such accompanying drawings illustrate the embodiments of the present invention which are used to describe the principles of the present invention. The embodiments are illustrated by way of example and not by way of limitation in the figures of the accompanying drawings in which like references indicate similar elements. It should be noted that references to “an” or “one” embodiment in this invention are not necessarily to the same embodiment, and they mean at least one. In the drawings:

FIG. 1 illustrates a charging and ambience monitoring portable device, in accordance with an embodiment of the present invention;

FIG. 2 illustrates a system in accordance with an embodiment of the present invention;

FIG. 3 illustrates an example block diagram of the operational steps in accordance with some example embodiments of the present invention; and

FIG. 4 illustrates a block diagram of the server for managing ambient conditions of a user, in accordance with an embodiment of the present invention.

### DETAILED DESCRIPTION OF THE INVENTION

The detailed description set forth below in connection with the appended drawings is intended as a description of various embodiments of the present invention and is not intended to represent the only embodiments in which the present invention may be practiced. Each embodiment described in this disclosure is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details.

The proposed invention relates to a portable device. The portable device may be a charging apparatus for charging smart wearable devices of a user, especially an electronic ring with Integrated Environmental Monitoring. The portable device may be configured to collect and monitor data related to ambience of a user, and may also control Internet of Things (IoT) devices in surroundings of the user. The portable device may further be configured to process and store data related to the ambience of the user and also operate with data collected by the wearable device, to provide feedback to the user related to impact of various aspects of ambience of the user. The portable device may also control the IoT devices to control various aspects of ambience of the user for promoting user's wellness.

The portable device may be configured to charge a smart wearable device, and also be configured to monitor conditions in ambience of the user, for assessing impact of ambience of user on his lifestyle.

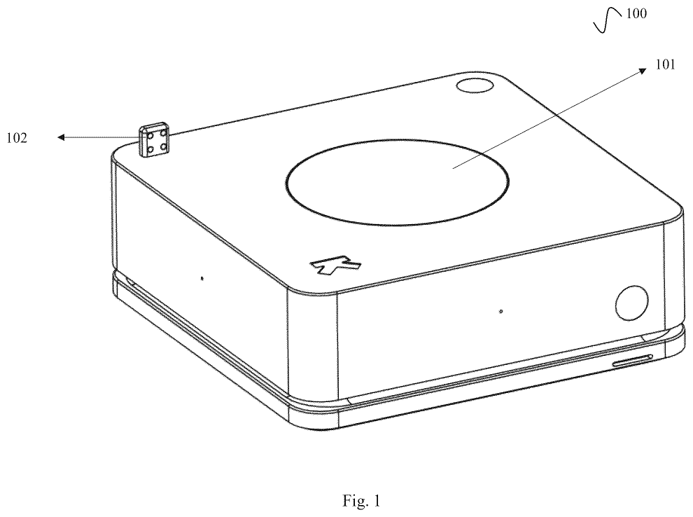

FIG. 1 illustrates a charging and ambience portable device, in accordance with an embodiment of the present invention. FIG. 1 shows the overall design and external appearance of the portable device, including the housing, the charging dock specifically shaped to hold and wirelessly charge a smart ring, and the placement of various environmental sensors embedded in/around the device. The portable device 100 may be designed in shape of a rectangular pod and configured to rest horizontally on a surface. The portable device 100 may include one or more charging docks configured to wirelessly recharge a smart ring or similar wearable device. A wireless charging dock is a convenient way to charge electronic devices simultaneously without having to plug them in. Each dock comprises a wireless charging coil, which may comply with the Qi standard or a proprietary charging standard. The dock includes magnetic or mechanical alignment features to securely hold the wearable during charging. The power source for the charging dock may be an internal rechargeable battery or an external power supply connected via USB-C or equivalent.

The portable device 100 may comprise a Printed Circuit Board (PCB). A plurality of sensors may be mounted on the PCB. The PCB may comprise any type of PCB, including but not limited to a single sided PCB, double sided PCB, multi layered PCB, and/or a flexible PCB. The PCB may include a plurality of sensors (collectively referred to as sensors) and a controller configured to interact with the plurality of sensors. The controller may be configured to couple with a memory of its own or a memory separately mounted on the PCB, for storing data acquired from the sensors.

In one implementation, the plurality of sensors may include one or more sound level sensors for measuring intensity of noise in surroundings of the portable device 100. The one or more sound level sensors may measure noise with an accuracy of 3 dB (decibel) in a range of 30 dB to 110 dB. The sound level sensors may also be useful in monitoring snoring sounds of the user when he is asleep. The plurality of sensors may also include one or more photodetectors for monitoring intensity of light in the surroundings of the portable device 100. The photodetectors may measure illuminance by converting light energy to electrical signals. The photodetectors respond to changes in the amount of light received, and may monitor the intensity of light during various times of the day.

The portable device 100 may also be configured to measure various environmental conditions in the ambience of the user, such as humidity, temperature, air quality, and/or other allergens in the air by utilising humidity sensors, temperature sensors, and air-quality sensors. The sensors are arranged and mounted to minimize thermal interference from the charging coil and device electronics, with enclosures or membranes that allow accurate environmental sensing. The air-quality sensors may monitor presence of organic compounds, particulate matters and other air-borne impurities in surroundings of the portable device 100. The air quality sensors may capture deterioration in quality of air in the ambience, due to factors such as indoor air pollution or smoking habits of the user. The portable device 100 may further utilise Radio Frequency (RF) meters for measurement of electromagnetic radiations that a user may be exposed to. The RF meter may measure the electromagnetic radiations emitted from various electronic devices in the vicinity of the user, such as mobile phones and wireless communication towers.

For scanning overall environment of the user, the controller may further be connected with an Infrared (IR) camera or proximity sensor provided in the portable device 100. This sensor is configured to detect the presence or movement of a user in proximity to the device. The detection of user presence may trigger changes in sensor sampling rates, activate display indicators, or influence power management decisions. The IR camera may capture values of movement of the user. The controller may also be connected to a microphone and a speaker. The microphone may enable the portable device 100 to receive voice commands of the user. The speaker may be utilised for playing wellness music for the user and also to provide alarms and alert to the user.

The portable device 100 may be connected with a server and/or one or more IoT devices through a radio based wireless module. The wireless module may work on one or more of Bluetooth, Wi-Fi, Near Field Communication (NFC). The wireless module may be mounted on the PCB to wirelessly communicate plurality of physiological data and environmental data to a server. The wireless module may also enable the controller to communicate with the IoT devices. The portable device 100 may further comprise a power source such as a battery for powering the plurality of sensors, the controller, and the radio based wireless module. The portable device 100 may further comprise a port/connector to receive power, for example a Universal Serial Bus (USB) port.

The portable device 100 may further be configured to hold a smart wearable device 102. In one embodiment the smart wearable device 102 may be an electronic ring, for charging. The portable device 100 may comprise a circuitry for wireless charging of the electronic ring. For wireless charging, the portable device 100 may comprise the wireless charging coil present on a surface of the device. Electromagnetic field generated by the wireless charging coil may get coupled with a coil of the electronic ring when the electronic ring is present in contact with the surface. Through coupling of the electromagnetic field, power from the portable device 100 may be received and stored in the battery of the electronic ring. The portable device 100 may also comprise a power converter for converting Alternating Current (AC) wall voltage may be converted to a Direct Current (DC) for supply of the DC current to the wireless charging coil.

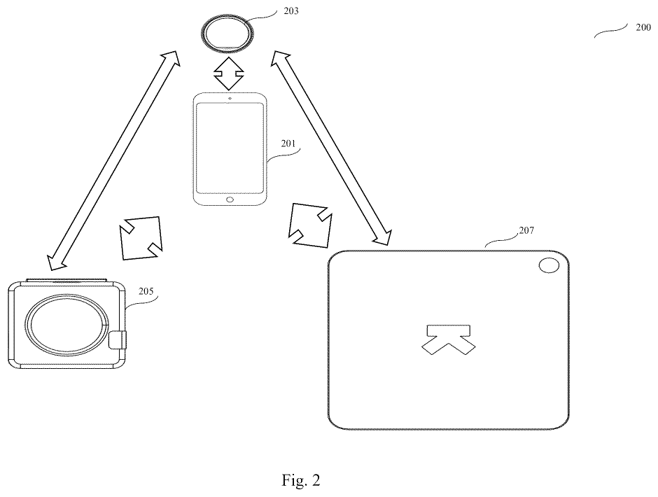

FIG. 2 illustrates a system 200 in accordance with an embodiment of the present disclosure. As shown in FIG. 2, a ring 203, a ring charger 205 and portable devices 207 are always in communication with a phone 201. The ring 203 is further in communication with the portable device 207 and the ring charger 205. When anyone leaves the vicinity of the phone 201, an alert is popped up on the phone 201. When the user presses the alert on the smartphone 201, the message is passed between devices to reach the intended device which turn on an audio alert on the device of interest. As shown in FIG. 2, the present invention discloses a compact, portable charger 205 for smart rings 203 that also integrates environmental sensors. It wirelessly recharges the ring 203 and simultaneously monitors environmental conditions such as temperature, humidity, and air quality. The charger 205 functions both while the ring 203 is docked and independently as a standalone environmental tracker, with data transmitted via BLE (Bluetooth Low Energy) to a paired device 201.

In one implementation (not shown in FIG. 2), the portable device 207 lies a smart ring docking cavity, specifically shaped to securely hold a smart ring 203 during charging. Beneath this cavity is the wireless charging coil configured according to established inductive charging standards, such as the Qi protocol or a proprietary technology. This coil delivers power wirelessly to the smart ring 203 through electromagnetic induction when the ring is placed in the dock. Integrated alongside the charging coil is a sensor module mounted on a printed circuit board (PCB), which hosts multiple environmental sensors. These sensors include a temperature sensor for monitoring ambient temperature, a humidity sensor for detecting moisture levels in the air, an air quality sensor capable of measuring volatile organic compounds (VOCs) and other pollutants, and optionally an ambient light sensor that tracks luminance and light exposure.

The present invention may in some embodiments may also comprise of a Microcontroller and BLE Module that coordinates sensor data and communicates with external devices. The invention also comprises of a battery/power source which can be rechargeable Li-Po battery or USB-C input. The system 200 has a compact layout in which sensor and charging modules are co-located using low-profile components, EMI shielding, and system-in-package architecture.

In one implementation, the portable device 207 employs several thermal and electromagnetic interference (EMI) mitigation strategies to ensure the accuracy and reliability of environmental sensing. A printed circuit board (PCB) design is utilized to effectively separate and shield the wireless charging coil from sensitive sensor circuits. Dedicated EMI shielding layers, composed of conductive materials, are strategically placed between the charging components and sensor modules to block electromagnetic noise generated during inductive charging. The portable device 207 may employs system-in-package architecture to integrate charging coils, sensors, and controller into a compact form factor. EMI shielding is incorporated to minimize interference between the charging system and sensitive sensor electronics.

In one implementation, the portable device 207 further incorporates thermal isolation zones within the PCB layout. These zones physically separate heat-generating elements, such as the wireless charging coil and power management circuits, from the environmental sensors. Use of thermally insulating materials and air gaps within the housing further minimizes heat transfer. This careful thermal management prevents temperature fluctuations caused by charging from skewing sensor readings, thus maintaining precise ambient measurements. This enable the seamless integration of wireless charging and environmental sensing in a compact form factor without compromising sensor performance.

Alternate embodiments of the portable device 207 may include multi-ring charging docks with similar integrated environmental sensing, or adaptations for other wearables such as smartwatches or earbuds. Additionally, enhanced versions may incorporate advanced sensors, expanded data logging capabilities, or compatibility with smart home automation systems.

In alternate embodiments, the portable device 207 may be adapted to support other types of wearable technology beyond smart rings. For instance, one embodiment may include chargers for smartwatches or wireless earbuds that incorporate similar environmental sensor integration, enabling consistent monitoring of ambient conditions regardless of the wearable form factor. Another embodiment may involve docking stations equipped with enhanced data logging functionality or compatibility with IoT ecosystems, allowing the device to store and transmit environmental and biometric data over extended periods and integrate with broader smart home or health monitoring systems.

Unlike existing technologies that separate environmental sensing and wearable charging, the present invention combines both in a single, portable device. None of the current smart ring chargers on the market provide ambient sensing capabilities. Furthermore, the charger 205 can operate as a standalone environmental tracker, even without the ring, which enhances its uniqueness and utility.

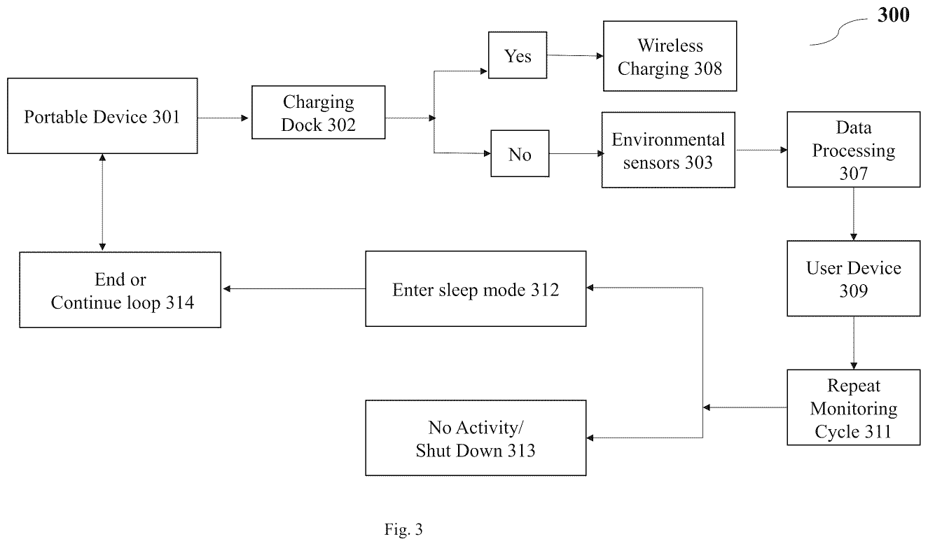

FIG. 3 illustrates an example block diagram of the operational steps in accordance with some example embodiments of the present invention. The system 300 operational cycle begins when the portable device 301 is powered on, either via the internal rechargeable battery or an external power source such as a USB-C input. The portable device 301 enters its active state from standby. The system 300 first verifies the availability of power. If no adequate power is detected, either from the battery or USB-C input, the portable device 301 enters a low-power sleep mode to conserve energy. If power is available, it proceeds to the next step. Upon confirming power availability, the microcontroller initializes all essential hardware components. This includes activation of the environmental sensors 303, the BLE (Bluetooth Low Energy) communication module, the wireless charging coil, and any associated supporting circuits. The system 300 uses detection mechanisms, such as a magnetic sensor, contactless proximity detection, or mechanical alignment switch, to determine if a smart ring 203 is placed in the charging dock 302. If a ring is detected, the system 300 initiates the wireless charging process 308. If no ring is present, the system 300 continues with environmental data acquisition without initiating charging.

In another implementation, the portable device 301 reads and collects environmental data from a plurality of onboard sensors 303 such as Temperature Sensor 304 which Monitors ambient temperature, Humidity Sensor 305 which Measures relative humidity in the environment. Air Quality Sensor 306 which detects pollutants or volatile organic compounds (VOCs), and other environmental sensors. This data is sampled either continuously or at fixed intervals. The raw sensor 303 readings are processed by the microcontroller. The Processing 307 may include noise filtering, normalization, timestamping, and comparison against preset environmental thresholds (e.g., VOC level above safe limits, humidity above 80%). Alerts or status flags may be generated based on this analysis. Once processed, the environmental and system status data is transmitted wirelessly to a paired mobile device, computer, or IoT gateway using BLE, Wi-Fi, or NFC, depending on the implementation.

In another implementation, the portable device 301 logs the environmental data either locally in onboard memory or remotely by syncing it with a mobile app or cloud service for extended analytics, trend tracking, or health monitoring. After each data collection cycle, the system 300 waits for a predefined time interval (e.g., 60 seconds) before repeating the environmental sensing and data handling processes. At any point, if the portable device 301 detects inactivity, low battery condition, or prolonged absence of a smart ring 203 in the dock 302, it can autonomously enter a low-power sleep mode 312 to conserve energy. The system 300 remains in this state until reawakened by an event trigger such as power input or ring placement. The process loops back to repeat the sensing 314 and monitoring cycle 311 unless the portable device 301 is turned off manually or shuts down 313 due to complete battery depletion.

In another implementation, the smart ring 203 is detected in the charging dock 302, the system 300 initiates the wireless charging process 308 and the charging coil is activated. Charging parameters such as voltage, current, and charge state are monitored by the microcontroller to ensure safe and efficient energy transfer. The portable device 301 includes the wireless communication module, which may use Bluetooth Low Energy (BLE), Wi-Fi, or Near Field Communication (NFC) protocols. This module enables the transmission of processed sensor data 307 to external systems 309, including smartphones, cloud services, or IoT hubs. The communication module remains operational regardless of the presence of a wearable device 310 in the charging dock 302, ensuring that environmental data is collected and transmitted continuously.

In another implementation, the portable device 301 is powered by an internal rechargeable lithium-polymer (Li-Po) battery. The battery may be recharged via a standard USB-C interface. Power management circuitry is included to ensure safe charging and discharging, and to regulate voltage supplied to the internal components. The battery capacity is selected to provide sufficient runtime for both charging operations and continuous environmental monitoring during portable use.

The present invention may in some embodiments may include one or more portable device 301 connected to each other via wireless network. The portable device 301 may further be coupled to a server 306. The server 306 may be hosted locally or over a cloud network. The portable device 301 may transmit ambient data (alternatively referred to as one or more sensor data) captured from the plurality of sensors. The server 306 may also receive physiological data of the user monitored using the smart wearable device 310. The server 306 may run programmed instructions for processing the one or more sensor data and carrying out an algorithm for analysing impact of ambient conditions on lifestyle of the user, based on the one or more sensor data and the user data. The server 306 may further be configured to interact with a user device 309 through the wireless network. The user device 309 may be a processing device, such as a smartphone, tablet, or a laptop configured to run an application or software. The application or software may be used to display one or more of the sensor data, the user data, and the impact of the ambient conditions on the user. The server 306 may provide details of analysis of the ambient conditions to the user as a feedback to the user, to enable him to monitor his lifestyle. Based on the details of analysis of the ambient conditions, the server 306 may communicate with the portable device 301 to automatically control IoT devices connected to the portable device 301 for ensuring optimum health and wellness of the user.

In another implementation, the server 306 may utilise respiratory flow rate captured by the smart wearable device, to determine an extent to which snoring is present. Based on a snoring of the user, the server 306 may determine sleep patterns of the user and may calculate quality of sleep of the user, and an amount of time the user was in light sleep and deep sleep conditions. Based on the sleep patterns of the user, the portable device 301 may play soothing music at night to help the user to fall asleep.

In another implementation, based on user preference and sleep patterns of the user, determined by the server 306, the server 306 may further determine a time slot during a day of the user where the user may consume caffeine so as to not impact his sleep. The portable device 301 may command a coffee machine connected to it wirelessly, to produce coffee in the morning and disable the coffee machine post afternoon to ensure a good sleep for the user at night. In another scenario, the portable device 301 may also turn off an IoT connected light when one of the smart wearable devices 310 and/or the portable device 301 may detect that the user has fallen asleep and turn it on when the user wakes up.

In another implementation, the server 306 may determine impact of the ambient conditions on lifestyle of the user and may control IoT devices via the portable device 100 for ensuring wellness of the user. The server 306 may also provide guidance to the user on the user device 209 to improve their sleep hygiene in order to improve overall wellness and sleep quality. For an example, if the user is determined to be a smoker and local air quality sensors detects a decrease in air quality, an alert may be provided to the user not to smoke. Alternatively, the server 306 may instruct the portable device 301 to turn on an IoT enabled air purifier.

In yet another implementation, one or more portable device may create a wireless mesh among themselves and track position of the smart wearable device at all times in premises of the user, to form a heat map of the user's movements and holistically determined overall ambient conditions that the user is exposed to. The user may receive suggestions on the user device 209 as to which portable device 301 offers best environment for different functions during the day and for good sleep at night.

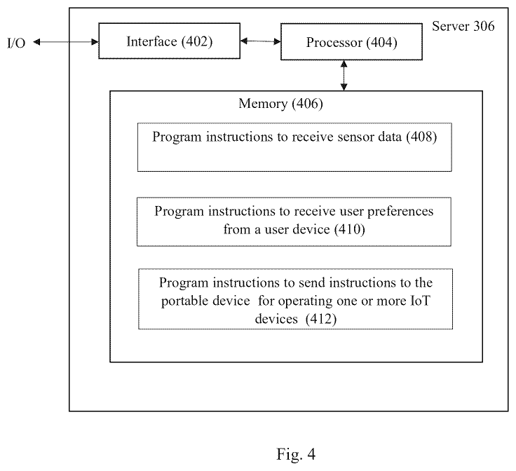

FIG. 4 illustrates a block diagram of the server 306 for managing ambient conditions of a user, in accordance with an embodiment of the present invention. The server 306 may comprise one or more network interfaces 402 (e.g., wired, wireless, etc.), at least one processor 404, and a memory 406. The one or more network interfaces 402 may be used to provide input or fetch output from the server 306. The one or more network interfaces 402 may be implemented as a Command Line Interface (CLI) or a Graphical User Interface (GUI). Further, Application Programming Interfaces (APIs) may also be used for remotely interacting with edge systems and cloud servers.

The processor 404 may include one or more general purpose processors (e.g., INTEL® or Advanced Micro Devices® (AMD) microprocessors) and/or one or more special purpose processors (e.g., digital signal processors or Xilinx® System on Chip (SOC) Field Programmable Gate Array (FPGA) processor), MIPS/ARM-class processor, a microprocessor, a digital signal processor, an application specific integrated circuit, a microcontroller, a state machine, or any type of programmable logic array. The microcontroller serves as the central controller, managing sensor polling, data processing, power management, and wireless communication. The controller executes firmware to calibrate sensor readings, filter noise, and convert raw data into standardized formats. It also timestamps data and manages communication protocols such as Bluetooth Low Energy, Wi-Fi, or NFC. The controller supports power management to conserve battery life, including sleep modes and wake-on-presence functionality.

The memory 406 of the server 306 may store program instructions for managing ambient conditions of a user. Functional code stored in the memory 406 may include program instructions to determine to receive sensor data and user activity data 309, program instructions to to receive user preferences from a user device 410, and program instructions to to send instructions to the portable device for operating one or more IoT devices 412.

The program instructions to determine to receive sensor data and user activity data 408 cause the processor to receives sensor data from the portable device 100. The program instructions to to receive user preferences from a user device 410 cause the processor to receive the user preference from the user device 408 through a software or any application. Further, the program instructions to send instructions to the portable device for operating one or more IoT devices 412 cause the processor to sends instructions to the portable device 100 to control the connected IoT devices based on the sensor data and user preferences. Furthermore, the server 306 is configured to receive information regarding the usage patterns of the IoT devices through the portable device 100 and provide recommendations to the user for storing the usage pattern information as user preferences. The server 306 then sends the necessary instructions to the portable device 100 for operating the one or more IoT devices based on these preferences.

In one implementation the portable device 100 is configured to control an Air Conditioning (AC) unit by setting it to 27 degree Celsius at 10:00 PM every day. The instructions for this operation are provided by the user through a user device 410 such as a smartphone, where an application or software installed on the user device 410 allows the user to input their preferences. Such preferences are transmitted to the server 306. Further the server 306 processes the instructions and stores the information in its memory 406. At the specified time (i.e. at 10 pm every day), the server sends a command to the portable device 100 to switch ON the AC unit at the desired temperature (27 degree Celsius) based on the preference of user.

The present invention transforms a traditionally passive accessory, the charger into a multifunctional wellness tool. By integrating real-time environmental monitoring with wearable device charging capabilities, it ensures seamless and continuous data collection, even when the wearable is not in use. This enhances the depth and accuracy of health analytics, enabling users to make more informed lifestyle decisions. Its smart design supports integration with home automation systems, offering timely alerts such as air quality warnings, while remaining lightweight and portable for ease of use across diverse environments, including during travel.

The present invention offers a dynamic solution for managing and enhancing personal wellness. It not only charges a wearable device, such as a smart ring, but also continuously monitors environmental conditions, including temperature, humidity, air quality, and ambient light, which are known to influence sleep quality, physical recovery, and overall well-being. By analysing these environmental parameters in real time and correlating them with biometric data collected from the wearable, the invention empowers users with actionable insights. The present invention evaluates the effects of environmental conditions on the user's health and thereby contributes to improved wellness outcomes.

In the above detailed description, reference is made to the accompanying drawings that form a part thereof, and illustrate the best mode presently contemplated for carrying out the invention. However, such description should not be considered as any limitation of scope of the present unit. The structure thus conceived in the present description is susceptible of numerous modifications and variations, all the details may furthermore be replaced with elements having technical equivalence.

We claim:

1. A portable device, comprising:
one or more charging docks, wherein the charging dock provides charging to a wearable device connected to the charging dock;
a plurality of sensors configured to monitor environment conditions, wherein the environment conditions includes at least one of temperature, humidity, air quality, luminance;
a controller connected with the plurality of sensors, wherein the controller is configured to process data received from the plurality of sensors; and
a wireless communication module connected with the controller to transmit the processed data;
wherein the device transmits the processed data, irrespective of the connection at the charging dock.

2. The portable device of claim 1, further comprises an infrared camera connected with the controller to monitor the user activity.

3. The portable device of claim 1, wherein the wearable device is a smart ring.

4. The portable device of claim 1, wherein the charging dock comprises a wireless charging coil.

5. The portable device of claim 1, wherein the wireless communication module operates using Bluetooth, Wi-Fi, Near Field Communication (NFC).

6. The portable device of claim 1, wherein the one or more charging docks and the plurality of sensors are positioned as per system-in-package architecture.

7. The portable device of claim 1, wherein the one or more charging docks and the plurality of sensors are positioned to provide EMI shielding.

8. The portable device of claim 1, further comprising an internal rechargeable battery powering the charging dock and environmental sensors.

9. The portable device of claim 1, wherein the one or more charging docks are capable of docking different wearable devices.

10. The portable device of claim 1, further comprising a user interface, wherein the user interface includes a touch display.
